(19) United States
(12) Patent Application Publication
(10) Pub. No.: US 2025/0194393 A1
(43) Pub. Date: Jun. 12, 2025

(54) APPARATUS FOR MANUFACTURING DISPLAY DEVICE AND METHOD FOR MANUFACTURING DISPLAY DEVICE

(71) Applicant: Samsung Display Co., LTD., Yongin-si (KR)

(72) Inventors: Hwan Jin KIM, Yongin-si (KR); Sung Yong KANG, Yongin-si (KR)

(21) Appl. No.: 18/807,713

(22) Filed: Aug. 16, 2024

(30) Foreign Application Priority Data
Dec. 12, 2023 (KR) 10-2023-0179531

(51) Int. Cl. H10K 71/50; B41J 3/407; B41J 3/44; B41J 11/00; B41J 11/66; B41M 3/00; B41M 5/00; B41M 7/00; H10K 59/12; H10K 59/80

(52) U.S. Cl. CPC H10K 71/50; B41J 3/407; B41J 3/44; B41J 11/00214; B41J 11/66; B41M 3/006; B41M 5/0047; B41M 7/0009; B41M 7/0027; B41M 7/0081; H10K 59/1201; H10K 59/873

(57) ABSTRACT

An apparatus for manufacturing a display device includes an application head which applies an adhesive material to a subject, and a selective curing module which curs a portion of the adhesive material, where the selective curing module cures an edge portion of the adhesive material.

This application claims priority to Korean Patent Application No. 10-2023-0179531, filed on Dec. 12, 2023, and all the benefits accruing therefrom under 35 U.S.C. § 119, the content of which in its entirety is herein incorporated by reference.

### BACKGROUND

### 1. Field

The disclosure relates to an apparatus for manufacturing a display device and a method for manufacturing a display device.

### 2. Description of the Related Art

As the information society develops, the demand for display devices for displaying images has increased in various fields. The display devices may be display devices such as liquid crystal displays (LCDs), field emission displays (FEDs), or light emitting displays (LEDs). The light emitting display may include an organic light emitting display including organic light emitting diode elements as light emitting elements, an inorganic light emitting display including inorganic light emitting diode elements as light emitting elements, or the like.

The display device may include a display panel including light emitting elements, and a window member may be disposed above the display panel to protect the display panel from an external shock. The window member may be disposed on the display panel through an adhesive member.

### SUMMARY

Embodiments of the disclosure provide an apparatus for manufacturing a display device and a method for manufacturing a display device in which adhesive strength and adhesive reliability of an adhesive member adhering a display panel and a window member to each other are improved.

Embodiments of the disclosure also provide an apparatus for manufacturing a display device and a method for manufacturing a display device in which process efficiency and productivity are improved.

However, embodiments of the disclosure are not restricted to those set forth herein. The above and other features of embodiments of the disclosure will become more apparent to one of ordinary skill in the art to which the disclosure pertains by referencing the detailed description of the disclosure given below.

According to an embodiment of the disclosure, an apparatus for manufacturing a display device includes an application head which applies an adhesive material to a subject, and a selective curing module which cures a portion of the adhesive material, where the selective curing module cures an edge portion of the adhesive material.

In an embodiment, the apparatus may further include a transfer module including a carrier film and a roller group which provides a driving force to the carrier film, where the carrier film provides a space where the subject is seated.

In an embodiment, the application head and the selective curing module may be respectively positioned on opposite sides with the carrier film interposed therebetween.

In an embodiment, the carrier film may be a light transmitting film.

In an embodiment, the roller group may include an unwinding roller which unwinds the carrier film and a winding roller which winds the carrier film.

In an embodiment, the selective curing module may include a first curing device which irradiates the adhesive material with light, and a light blocking film which blocks a portion of the light, and the light blocking film includes a non-transmissive area blocking some of the light and a transmissive area which transmits a portion of the light therethrough.

In an embodiment, the light blocking film may be provided with an opening which transmits the light therethrough.

In an embodiment, the subject may include a release film, and alignment marks may be formed on the release film by the adhesive material applied from the application head.

In an embodiment, the release film may be a light transmitting film.

In an embodiment, the apparatus may further include a first lamination device which laminates a display panel on the subject to which the adhesive material is applied.

In an embodiment, the apparatus may further include a second curing device which entirely cures the adhesive material included in the subject on which the display panel is laminated, where the second curing device may form an adhesive member by curing the adhesive material.

In an embodiment, the apparatus may further include a second lamination device which laminates a window member on the subject including the display panel and the adhesive member.

In an embodiment, the apparatus may further include a cutting device cutting an edge portion of the subject.

In an embodiment, the apparatus may further include a film removing device which removes the release film disposed on the adhesive member.

In an embodiment, the adhesive material may include an optical clear resin having a liquid form.

According to an embodiment of the disclosure, there is provided a method for manufacturing a display device, including, applying an adhesive material onto a release film, selectively curing an edge portion of the adhesive material, laminating a display panel on the release film and the adhesive material, forming an adhesive member by curing an entirety of the adhesive material, and removing the release film and laminating a window member on the display panel and the adhesive member.

In an embodiment, the applying of the adhesive material and the selectively curing of the edge portion of the adhesive material may be at least partially simultaneously performed.

In an embodiment, in the laminating the display panel, portions of the adhesive material except for the selectively cured edge portion of the adhesive material may be in a liquid form.

In an embodiment, the release film may be removed after the entirety of adhesive material is cured.

In an embodiment, the method may further include cutting edge portions of the display panel, the adhesive member, and the release film.

According to an apparatus for manufacturing a display device and a method for manufacturing a display device according to an embodiment of the disclosure, adhesive strength and adhesive reliability of an adhesive member adhering a display panel and a window member to each other may be improved.

According to the apparatus for manufacturing a display device and the method for manufacturing a display device according to an embodiment of the disclosure, process efficiency and productivity may be improved.

The effects of the disclosure are not limited to the aforementioned effects, and various other effects are included in the specification.

### BRIEF DESCRIPTION OF THE DRAWINGS

The above and other aspects and features of embodiments of the disclosure will become more apparent by describing in detail embodiments thereof with reference to the accompanying drawings, in which:

FIG. 1 is a perspective view illustrating a display device according to an embodiment;

FIG. 2 is a cross-sectional view taken along line I-I′ of FIG. 1;

FIG. 3 is a cross-sectional view illustrating a display panel according to an embodiment;

FIGS. 4 and 5 are cross-sectional views illustrating an apparatus for manufacturing a display device according to an embodiment;

FIG. 6 is a plan view illustrating an apparatus for manufacturing a display device in a state in which an adhesive material is applied onto a release film according to an embodiment;

FIG. 7 is a flowchart illustrating a method for manufacturing a display device according to an embodiment;

FIG. 8 is a cross-sectional view illustrating process S100 of FIG. 7;

FIG. 9 is a cross-sectional view illustrating processes S100 and S200 of FIG. 7;

FIG. 10 is a cross-sectional view illustrating process S200 of FIG. 7;

FIG. 11 is a cross-sectional view illustrating processes S100 and S200 of FIG. 7;

FIG. 12 is a cross-sectional view illustrating processes S200 and S300 of FIG. 7;

FIG. 13 is a cross-sectional view illustrating process S400 of FIG. 7;

FIG. 14 is a cross-sectional view illustrating process S500 of FIG. 7;

FIG. 15 is a cross-sectional view illustrating process S600 of FIG. 7; and

FIG. 16 is a cross-sectional view illustrating a portion of a display device in a state in which a window member is laminated on the display panel according to an embodiment.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. In contrast, when an element is referred to as being “directly on” another element, there are no intervening elements present. The same reference numbers indicate the same components throughout the specification.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

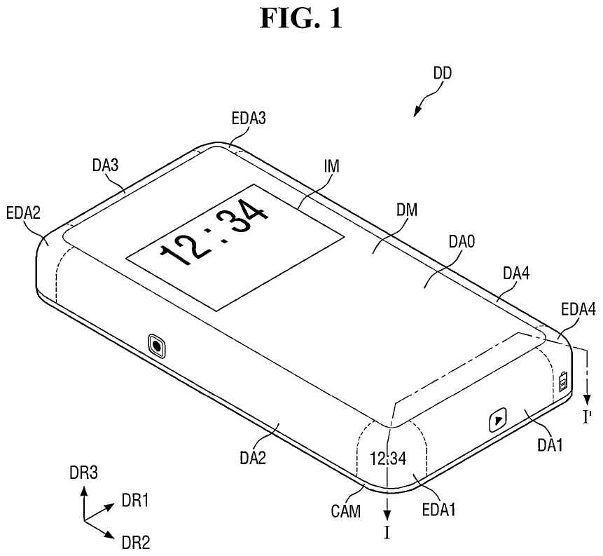

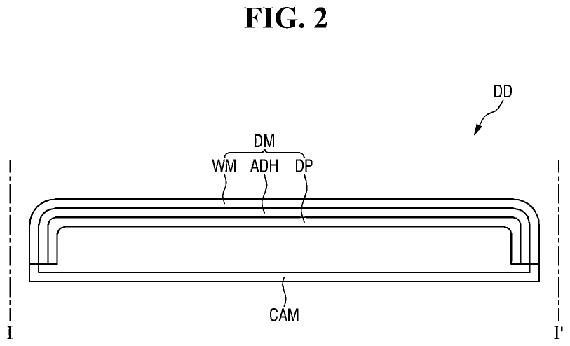

FIG. 1 is a perspective view illustrating a display device according to an embodiment. FIG. 2 is a cross-sectional view taken along line I-I′ of FIG. 1.

Referring to FIGS. 1 and 2, a display device DD according to an embodiment may refer to any electronic device provided with a display screen. The display device DD may display a moving image or a still image. For example, televisions, laptop computers, monitors, billboards, the Internet of Things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, camcorders, and the like, that provide display screens may be included in the display device DD. An embodiment where that the display device DD is a smartphone is illustrated by way of example in FIG. 1, but the disclosure is not limited thereto.

In an embodiment, as shown in FIG. 1, the display device DD may include a display module DM and a case member CAM.

The display module DM may include a display area. The display area DA may be an area displaying an image IM. The display area may include a main display area DA0, and first to fourth sub-display areas DA1, DA2, DA3, and DA4 and first to fourth corner display areas EDA1, EDA2, EDA3, and EDA4 that are adjacent to the main display area DA0.

The main display area DA0 may be parallel to a plane extending in a first direction DR1 and a second direction DR2. A normal direction of the main display area DA0 (i.e., a thickness direction of the display device DD) may be a third direction DR3.

In the drawings, the first direction DR1 and the second direction DR2 are horizontal directions, respectively, and cross each other. For example, the first direction DR1 and the second direction DR2 may be orthogonal to each other. In addition, the third direction DR3 may be a perpendicular direction crossing, for example, orthogonal to, the first direction DR1 and the second direction DR2. Directions indicated by the first to third directions DR1, DR2, and DR3 may be relative concepts and may be switched to other directions.

The main display area DA0 may display the image IM through a front surface. In an embodiment, for example, the main display area DA0 may display the image IM toward the third direction DR3. The image IM may include a still image as well as a dynamic image. In an embodiment, as shown in FIG. 1, the image IM may include a watch window and icons, for example.

The first sub-display area DA1 may be adjacent to the main display area DA0 on one side in the second direction DR2. The first sub-display area DA1 may display the image IM in a direction crossing the third direction DR3, which is the thickness direction of the display device DD. In an embodiment, for example, where an angle formed by the main display area DA0 and the first sub-display area DA1 is 90°, the direction crossing the third direction DR3 may be one side in the second direction DR2.

The second sub-display area DA2 may be adjacent to the main display area DA0 on the other side in the first direction DR1. The second sub-display area DA2 may display the image IM in a direction crossing the third direction DR3. In an embodiment, for example, where an angle formed by the main display area DA0 and the second sub-display area DA2 is 90°, the direction crossing the third direction DR3 may be the other side in the first direction DR1.

The third sub-display area DA3 may be adjacent to the main display area DA0 on the other side in the second direction DR2. The third sub-display area DA3 may display the image IM in a direction crossing the third direction DR3. In an embodiment, for example, where an angle formed by the main display area DA0 and the third sub-display area DA3 is 90°, the direction crossing the third direction DR3 may be the other side in the second direction DR2.

The fourth sub-display area DA4 may be adjacent to the main display area DA0 on one side in the first direction DR1. The fourth sub-display area DA4 may display the image IM in a direction crossing the third direction DR3. In an embodiment, for example, where an angle formed by the main display area DA0 and the fourth sub-display area DA4 is 90°, the direction crossing the third direction DR3 may be one side in the first direction DR1.

The first corner display area EDA1 may be positioned between the first sub-display area DA1 and the second sub-display area DA2. The first corner display area EDA1 may display the image IM in a direction crossing the thickness direction DR3 of the display device DD. In an embodiment, for example, where an angle formed by the main display area DA0 and the first corner display area EDA1 is 90°, the direction crossing the thickness direction DR3 may be at least one direction between the first direction DR1 and the second direction DR2. In another embodiment, the angle formed by the main display area DA0 and the first corner display area EDA1 may be greater or smaller than 90°.

The second corner display area EDA2 may be positioned between the second sub-display area DA2 and the third sub-display area DA3. The second corner display area EDA2 may display the image IM in a direction crossing the thickness direction DR3 of the display device DD. In an embodiment, for example, where an angle formed by the main display area DA0 and the second corner display area EDA2 is 90°, the direction crossing the thickness direction DR3 may be at least one direction between the first direction DR1 and the second direction DR2. In another embodiment, the angle formed by the main display area DA0 and the second corner display area EDA2 may be greater or smaller than 90°.

The third corner display area EDA3 may be positioned between the third sub-display area DA3 and the fourth sub-display area DA4. The third corner display area EDA3 may display the image IM in a direction crossing the thickness direction DR3 of the display device DD. In an embodiment, for example, where an angle formed by the main display area DA0 and the third corner display area EDA3 is 90°, the direction crossing the thickness direction DR3 may be at least one direction between the first direction DR1 and the second direction DR2. In another embodiment, the angle formed by the main display area DA0 and the third corner display area EDA3 may be greater or smaller than 90°.

The fourth corner display area EDA4 may be positioned between the fourth sub-display area DA4 and the first sub-display area DA1. The fourth corner display area EDA4 may display the image IM in a direction crossing the thickness direction DR3 of the display device DD. In an embodiment, for example, where an angle formed by the main display area DA0 and the fourth corner display area EDA4 is 90°, the direction crossing the thickness direction DR3 may be at least one direction between the first direction DR1 and the second direction DR2. In another embodiment, the angle formed by the main display area DA0 and the fourth corner display area EDA4 may be greater or smaller than 90°.

The main display area DA0 may be partially or completely surrounded by the first to fourth sub-display areas DA1, DA2, DA3, and DA4 and the first to fourth corner display areas EDA1, EDA2, EDA3, and EDA4.

In an embodiment, as shown in FIG. 2, the display module DM may include a display panel DP, an adhesive member ADH, and a window member WM.

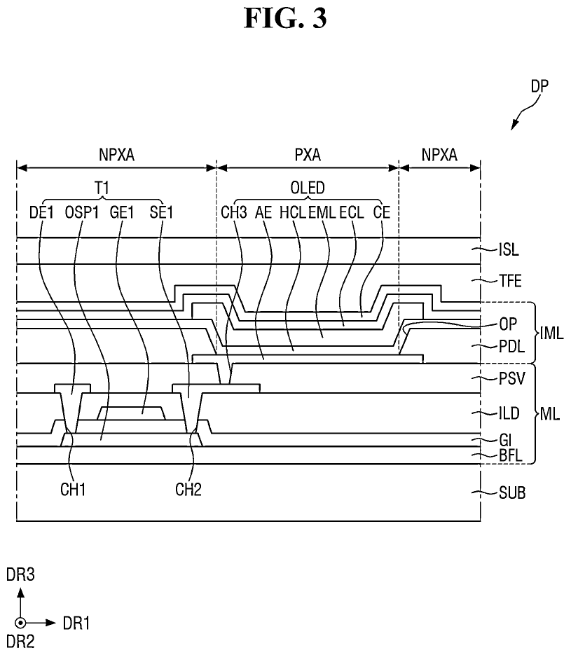

The display panel DP may include a light emitting display panel. The light emitting display panel may be, for example, an organic light emitting display panel or a quantum dot light emitting display panel. A light emitting layer of the organic light emitting display panel may include an organic light emitting material. A light emitting layer of the quantum dot light emitting display panel may include quantum dots, quantum rods, and the like. This is an example, and in the disclosure, the display panel DP is not particularly limited. In an embodiment, the display panel DP may be an organic light emitting display panel, which will be described later with reference to FIG. 3 as an example.

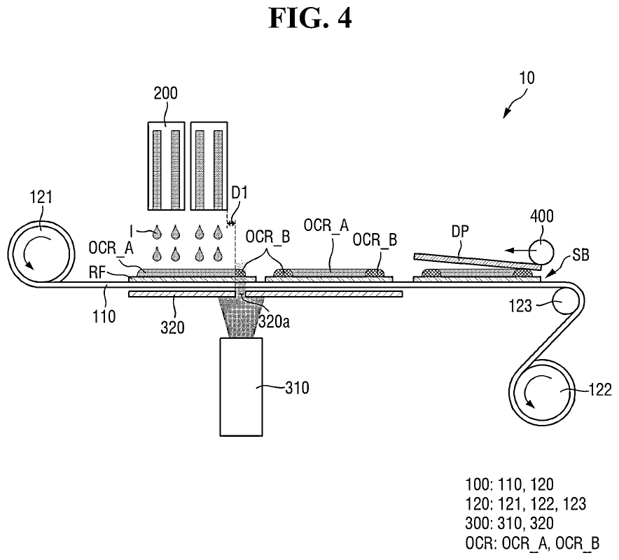

The adhesive member ADH may be disposed between the display panel DP and the window member WM. The adhesive member ADH may adhere the display panel DP and the window member WM to each other. The adhesive member ADH may include a general adhesive. In an embodiment, for example, the adhesive member ADH may include a pressure sensitive adhesive (PSA), an optical clear adhesive (OCA), or an optical clear resin (OCR). The adhesive member ADH may be formed by an apparatus 10 (see FIG. 4) for manufacturing a display device to be described later.

The window member WM may be disposed on the adhesive member ADH. The window member WM may cover the display panel DP. The window member WM may completely cover the main display area DA0, the first to fourth sub-display areas DA1, DA2, DA3, and DA4, and the first to fourth corner display areas EDA1, EDA2, EDA3, and EDA4 of the display device DD. A shape of the display panel DP may correspond to a shape of the window member WM. The window member WM may protect the display panel DP from an external shock and provide an input surface to a user.

The window member WM may have a transparent property such that light generated from the display panel DP may be transmitted therethrough. The window member WM may include a glass or plastic material. In some embodiments, where the window member WM includes glass, the window member WM may include chemically ion-substituted tempered glass. In another embodiment, where the window member WM includes plastic, the window member WM may include a polyimide (PI) film.

The case member CAM may be disposed below the display module DM. The case member CAM may have a predetermined color, but is not limited thereto. The case member CAM may be disposed at the outermost portion of the display device DD and may accommodate components therein. The case member CAM may include a bottom surface and sidewalls extending from the bottom surface. In addition, electronic modules (not illustrated) may be accommodated in an internal space defined by the bottom surface and the sidewalls.

The electronic modules may include, for example, a camera, a flash, a fingerprint sensor, a battery, and a function sensor. The function sensor may include a proximity sensor, a color density detection sensor, an illuminance sensor, a motion sensor, a heartbeat sensor, or the like. However, this is an example, and the function sensor is not limited to the above-described example. In addition, some of the camera, the flash, the fingerprint sensor, the battery, and the function sensor may be omitted, and other electronic modules may be further disposed.

The case member CAM may include a material having relatively higher rigidity than the display module DM. in an embodiment, for example, the case member CAM may include a plurality of frames and/or plates made of glass, plastic, metal, or combinations thereof. The case member CAM may stably protect components of the display device DD from an external shock.

FIG. 3 is a cross-sectional view illustrating a display panel according to an embodiment.

Referring to FIG. 3, an embodiment of the display panel DP may include a base layer SUB, a circuit element layer ML, a display element layer IML, a thin film encapsulation layer TFE, and a touch sensor layer ISL. The circuit element layer ML, the display element layer IML, the thin film encapsulation layer TFE, and the touch sensor layer ISL may be sequentially disposed on the base layer SUB.

The base layer SUB may include a transparent material. In an embodiment, for example, the base layer SUB may include a transparent insulating material such as glass or quartz. The base layer SUB may be a rigid substrate. However, the base layer SUB is not limited thereto, and may include plastic such as polyimide and may have flexible characteristics to be bent, folded, or rolled.

The circuit element layer ML may include a buffer film BFL, a first intermediate inorganic film GI, and a second intermediate inorganic film ILD, which are inorganic films, and an intermediate organic film PSV, which is an organic film. Materials of the inorganic films and the organic film are not particularly limited, and in an embodiment, the buffer film BFL may be optionally disposed or omitted.

A semiconductor pattern OSP1 of a transistor T1 may be disposed on the buffer film BFL. The semiconductor pattern OSP1 may be selected from amorphous silicon, polysilicon, or a metal oxide semiconductor.

The first intermediate inorganic film GI may be disposed on the semiconductor pattern OSP1. A control electrode GE1 of the transistor T1 may be disposed on the first intermediate inorganic film GI.

The second intermediate inorganic film ILD covering the control electrode GE1 may be disposed on the first intermediate inorganic film GI. An input electrode DE1 and an output electrode SE1 of the transistor T1 may be disposed on the second intermediate inorganic film ILD.

The input electrode DE1 and the output electrode SE1 may be connected to the semiconductor pattern OSP1, respectively, through a first through hole CH1 and a second through hole CH2, which are defined or formed through the first intermediate inorganic film GI and the second intermediate inorganic film ILD. In another embodiment, the transistor T1 may be modified to have a bottom gate structure.

The intermediate organic film PSV covering the input electrode DE1 and the output electrode SE1 may be disposed on the second intermediate inorganic film ILD. The intermediate organic film PSV may provide a flat surface.

The display element layer IML may be disposed on the intermediate organic film PSV. The display element layer IML may include a pixel defining film PDL and an organic light emitting diode OLED. The pixel defining film PDL may include an organic material. A first electrode AE may be disposed on the intermediate organic film PSV. The first electrode AE may be connected to the output electrode SE1 through a third through hole CH3 defined or formed through the intermediate organic film PSV. An opening OP may be defined in the pixel defining film PDL. The opening OP may expose at least a portion of the first electrode AE. In an embodiment, the pixel defining film PDL may be omitted.

In an embodiment, an emission area PXA may partially overlap the transistor T1.

A hole control layer HCL may be disposed in common in the emission area PXA and a non-emission area NPXA. A light emitting layer EML may be disposed on the hole control layer HCL. The light emitting layer EML may be disposed in an area corresponding to the opening OP. The light emitting layer EML may include an organic material and/or an inorganic material. The light emitting layer EML may generate predetermined colored light.

An electron control layer ECL may be disposed on the light emitting layer EML. A second electrode CE may be disposed on the electron control layer ECL.

The thin film encapsulation layer TFE may be disposed on the second electrode CE. The thin film encapsulation layer TFE may cover the second electrode CE. In an embodiment, a capping layer (not illustrated) covering the second electrode CE may be further disposed between the thin film encapsulation layer TFE and the second electrode CE. In such an embodiment, the thin film encapsulation layer TFE may directly cover the capping layer (not illustrated).

The touch sensor layer ISL may be disposed on the thin film encapsulation layer TFE. The touch sensor layer ISL may be directly disposed on the thin film encapsulation layer TFE and embedded in the display panel DP. The touch sensor layer ISL may include a plurality of touch electrodes for sensing a user's touch in a capacitance manner and touch lines connecting the plurality of touch electrodes and a touch driver TIC to each other. In an embodiment, for example, the touch sensor layer ISL may sense the user's touch in a mutual capacitance manner or a self-capacitance manner. In another embodiment, the touch sensor layer ISL may be disposed in the form of a separate substrate on the thin film encapsulation layer TFE.

Hereinafter, an embodiment of an apparatus 10 (see FIG. 4) for manufacturing a display device that forms the adhesive member ADH on the display panel DP of the display device DD and laminates the window member WM on the display panel DP and the adhesive member ADH will be described.

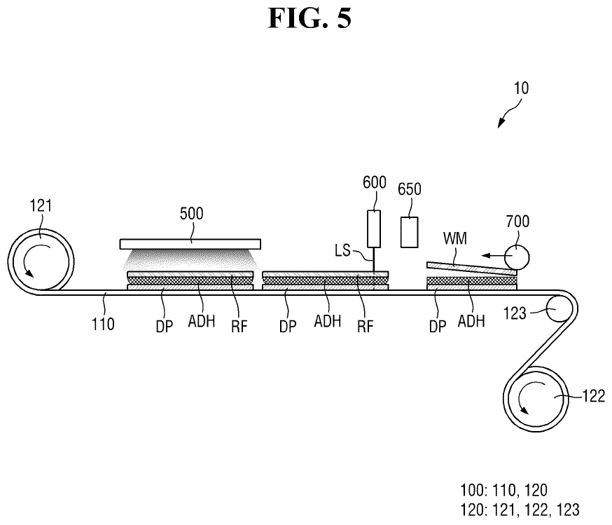

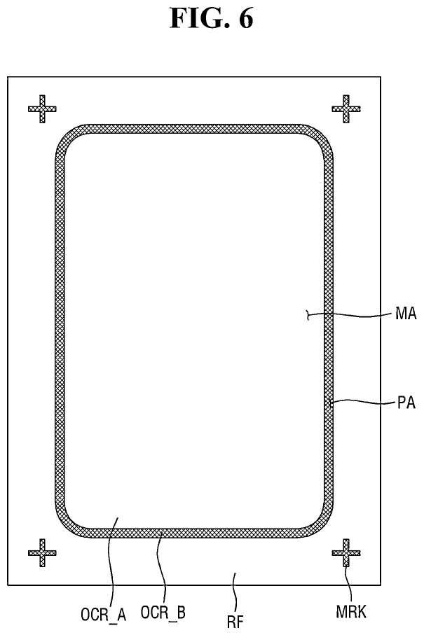

FIGS. 4 and 5 are cross-sectional views illustrating an apparatus for manufacturing a display device according to an embodiment. FIG. 6 is a plan view illustrating an apparatus for manufacturing a display device in a state in which an adhesive material is applied onto a release film according to an embodiment.

Referring to FIGS. 4 to 6 in addition to FIGS. 1 to 3, an embodiment of the apparatus 10 for manufacturing a display device may form the adhesive member ADH on the display panel DP and laminate the window member WM on the display panel DP and the adhesive member ADH. The apparatus 10 for manufacturing a display device may perform an applying process and a curing process of an adhesive material OCR and a lamination process of the window member WM.

The apparatus 10 for manufacturing a display device may apply the adhesive material OCR onto a release film RF. The apparatus 10 for manufacturing a display device may selectively cure a portion of the adhesive material OCR and then laminate the display panel DP on the selectively cured adhesive material OCR and the release film RF. The apparatus 10 for manufacturing a display device may form the adhesive member ADH by curing the entirety of the selectively cured adhesive material OCR. The apparatus 10 for manufacturing a display device may cut portions of the display panel DP, the adhesive member ADH, and the release film RF. The apparatus 10 for manufacturing a display device may remove the release film RF and laminate the window member WM on the display panel DP and the adhesive member ADH.

The apparatus 10 for manufacturing a display device may include a transfer module 100, an application head 200, a selective curing module 300, a first lamination device 400, a second curing device 500, a cutting device 600, and a second lamination device 700.

The transfer module 100 may transfer a subject SB disposed thereon. Before lamination of the display panel DP, the release film RF may be the subject SB, and after the lamination of the display panel DP, the display panel DP may be the subject SB.

The transfer module 100 may be a roll-to-roll equipment. In an embodiment, for example, the transfer module 100 may include a carrier film 110 and a roller group 120. The transfer module 100 may transfer the subject SB by seating the subject SB on the carrier film 110 that moves by unwinding and winding of the roller group 120. The apparatus 10 for manufacturing a display device according to an embodiment may perform a continuous process through a roll-to-roll process, and thus, process efficiency and productivity may be improved.

The carrier film 110 may move by a driving force generated by the roller group 120. The carrier film 110 may transfer the subject SB while moving by the driving force generated by the roller group 120.

The carrier film 110 may provide a space where the subject SB may be seated. In an embodiment, for example, the subject SB may be seated on an upper surface of the carrier film 110. When the subject SB is seated, the carrier film 110 may be disposed between the subject SB and a first curing device 310 to be described later.

In some embodiments, the carrier film 110 may be a light transmitting film. Since the carrier film 110 is disposed between the subject SB and the first curing device 310, the carrier film 110 may transmit light radiated from the first curing device 310 therethrough so that the light may reach the subject SB. Likewise, the release film RF may also be a light transmitting film.

The roller group 120 may include at least one roller. In an embodiment, for example, the roller group 120 may include an unwinding roller 121, a winding roller 122, and a direction change roller 123.

The unwinding roller 121 may rotate in at least one direction. The unwinding roller 121 may unwind the carrier film 110 while rotating in at least one direction. The unwinding roller 121 may generate a driving force so that the carrier film 110 may be unwound.

The winding roller 122 may rotate in at least one direction. The winding roller 122 may wind the carrier film 110 while rotating in at least one direction. The winding roller 122 may generate driving force so that the carrier film 110 may be wound.

In an embodiment, as illustrated in FIGS. 4 and 5, a rotation direction of the winding roller 122 and a rotation direction of the unwinding roller 121 may be the same as each other, but the disclosure is not limited thereto, and the unwinding roller 121 and the winding roller 122 may also rotate in opposite directions.

In some embodiments, both the unwinding roller 121 and the winding roller 122 may generate a driving force. However, the disclosure is not limited thereto, and only one of the unwinding roller 121 and the winding roller 122 may generate driving force, and the other of the unwinding roller 121 and the winding roller 122 may rotate together by the driving force.

The direction change roller 123 may change a moving direction of the carrier film 110. In an embodiment, for example, as illustrated in FIGS. 4 and 5, the direction change roller 123 may change the moving direction of the carrier film 110 so that the carrier film 110 that has moved in a horizontal direction moves in a diagonal direction. In an embodiment, as illustrated in FIGS. 4 and 5, the number of direction change rollers 123 may be one, but the disclosure is not limited thereto. In another embodiment, the direction change roller 123 may also be omitted or two or more direction change rollers 123 may also be included.

In some embodiments, the direction change roller 123 may rotate together by the driving force generated by at least one of the unwinding roller 121 and the winding roller 122. However, the disclosure is not limited thereto, and the direction change roller 123 may also generate driving force.

The application head 200 may apply ink I onto the subject SB. In an embodiment, for example, the application head 200 may apply the ink I onto the release film RF. In some embodiments, the application head 200 may include an inkjet printing device and a dispenser device.

The ink I may include the adhesive material OCR. In some embodiments, the adhesive material OCR may include a liquid optical clear resin OCR.

The adhesive material OCR may correspond to a shape of the display device DD (see FIG. 1), as illustrated in FIG. 6. In some embodiments, the adhesive material OCR may include an edge portion PA positioned at an edge and a central portion MA surrounded by the edge portion PA. In an embodiment where the adhesive material OCR is in a liquid form, the edge portion PA of the adhesive material OCR may include an inclined surface inclined toward an outward direction due to spreadability of the adhesive material OCR.

In some embodiments, the application head 200 may apply alignment marks MRK onto the release film RF. The alignment marks MRK may be disposed in an area other than an area where the center portion MA and the edge portion PA are disposed on the release film RF. The apparatus 10 for manufacturing a display device according to an embodiment may improve alignment accuracy during a lamination process of the display panel DP by applying the alignment marks MRK. In addition, since the alignment marks MRK are applied along with the application of the central portion MA and the edge portion PA of the adhesive material OCR, a separate process for forming marks may not be additionally performed, and thus, a process time may be shortened.

The selective curing module 300 may selectively cure a portion of the adhesive material OCR. In an embodiment, for example, as illustrated in FIG. 6, the selective curing module 300 may selectively cure the edge portion PA of the adhesive material OCR, and may not cure the central portion MA of the adhesive material OCR.

In some embodiments, the selective curing module 300 may include the first curing device 310 and a light blocking film 320.

The first curing device 310 may irradiate the adhesive material OCR with light. In an embodiment, for example, the first curing device 310 may irradiate the adhesive material OCR with ultraviolet rays, but is not limited thereto. The first curing device 310 may cure the adhesive material OCR by irradiating the adhesive material OCR with the light.

The light blocking film 320 may block at least some (or at least a portion)_of the light generated by the first curing device 310. The light blocking film 320 may transmit at least some of the light generated by the first curing device 310 therethrough. In an embodiment, as illustrated in FIG. 4, the light blocking film 320 may be provided with an opening 320a. In such an embodiment, the light blocking film 320 may transmit at least some of the light generated by the first curing device 310 through the opening 320a, and may block at least some of the light generated by the first curing device 310 through portions thereof other than the opening 320a.

However, the light blocking film 320 is not limited thereto, and may include a transmissive area and a non-transmissive area instead of the opening 320a and the portions thereof other than the opening. In an embodiment, for example, no opening is defined through the light blocking film 320, and the light blocking film 320 may transmit at least some of the light generated by the first curing device 310 through the transmissive area thereof and block at least some of the light generated by the first curing device 310 through the non-transmissive area thereof.

When moving by the carrier film 110, the edge portion PA of the adhesive material OCR may overlap the opening 320a or the transmissive area of the light blocking film 320 at a specific point in time. At the point in time when the edge portion PA of the adhesive material OCR and the opening 320a or the transmissive area of the light blocking film 320 overlap each other, the first curing device 310 may irradiate the adhesive material OCR with the light, that is, radiate or emit the light to the adhesive material OCR. Accordingly, a portion, for example, the edge portion PA, of the adhesive material OCR may be selectively cured. After a selective curing process, the edge portion PA may include a solid post-cured adhesive material OCR_B (i.e., a portion of the adhesive material in a solid state), and the central portion MA may include a liquid pre-cured adhesive material OCR_A (i.e., a portion of the adhesive material in a liquid state).

The apparatus 10 for manufacturing a display device according to an embodiment may easily control a shape of the adhesive member ADH by selectively curing the edge portion PA of the adhesive material OCR. In an embodiment, for example, as a time from a point in time after the liquid adhesive material OCR is applied to a point in time before the liquid adhesive material OCR is cured increases, an area occupied by the inclined surface of the edge portion PA may increase due to the spreadability. Therefore, by selectively curing the edge portion PA as soon as the adhesive material OCR is applied before a lamination process of the display panel DP and a lamination process of the window member WM to be described later are performed, it is possible to effectively prevent the inclined surface of the edge portion PA from spreading.

In addition, by maintaining the central part MA of the adhesive material OCR in a liquid form through the selective curing of the edge portion PA of the adhesive material OCR, surface quality of a lamination surface between the display panel DP and the adhesive material OCR in a subsequent lamination process of the display panel DP may be improved.

In the apparatus 10 for manufacturing a display device according to an embodiment, as illustrated in FIG. 4, the application head 200 and the selective curing module 300 may be respectively positioned on opposite sides with the carrier film 110 interposed therebetween. Accordingly, a horizontal distance between the application head 200 and the first curing device 310 or a horizontal distance D1 between the application head 200 and the opening 320a of the light blocking film 320 may be minimized. Therefore, by minimizing a time between the applying process and the selective curing process, it is possible to easily control a shape of the edge portion PA.

The first lamination device 400 may laminate the display panel DP on the release film RF and the adhesive material OCR. In an embodiment, as illustrated in FIG. 4, the first lamination device 400 may be a roll lamination device, but the disclosure is not limited thereto. In an embodiment, for example, the first lamination device 400 may be a vacuum lamination device.

The second curing device 500 may cure the adhesive material OCR. In an embodiment, the second curing device 500 may irradiate the adhesive material OCR with light. In an embodiment, for example, the second curing device 500 may irradiate the adhesive material OCR with ultraviolet rays, but is not limited thereto.

The second curing device 500 may entirely cure the adhesive material OCR. In an embodiment, for example, the second curing device 500 may entirely cure the adhesive material OCR without distinguishing between the central portion MA and the edge portion PA of the adhesive material OCR. The central portion MA that is not cured may be cured, thereby changing from a liquid form to a solid form, and the edge portion PA that has already been selectively cured may have no change in state or may have an increased curing degree. The adhesive member ADH may be formed by curing the adhesive material OCR.

The selective curing process of the first curing device 310 may be referred to as temporary curing, and a curing process of the second curing device 500 may be referred to as main curing, but the disclosure is not limited thereto.

In an embodiment, as illustrated in FIG. 5, the second curing device 500 cures the adhesive material OCR by irradiating the adhesive material OCR with the light, but the disclosure is not limited thereto. In an embodiment, the second curing device 500 entirely cures the adhesive material OCR, and may thus cure the adhesive material OCR through thermal curing or natural curing as well as through ultraviolet (UV) curing.

In the apparatus 10 for manufacturing a display device according to an embodiment, the main curing of the adhesive material OCR by the second curing device 500 may be performed in a state where the adhesive material OCR is covered with the release film RF. Accordingly, an area of the adhesive material OCR in contact with oxygen may be minimized, and a non-curing phenomenon or a reduction phenomenon in curing degree of the adhesive material OCR due to an oxygen inhibition effect may be effectively prevented.

In the apparatus 10 for manufacturing a display device according to an embodiment, the main curing of the adhesive material OCR by the second curing device 500 may be performed before the window member WM is laminated. As the curing degree of the adhesive material OCR increases, adhesive strength of the adhesive material OCR or the adhesive member ADH may be improved. Since the main curing of the adhesive material OCR is performed before the window member WM is laminated, adhesive strength of the adhesive member ADH to the window member WM may be improved.

The cutting device 600 may cut an edge portion of the adhesive member ADH. The edge portion of the adhesive member ADH including the inclined surface of the adhesive material OCR described above may be removed by the cutting device 600. An edge portion of the display panel DP and an edge portion of the release film RF may also be removed along with the edge portion of the adhesive member ADH. In some embodiments, a cutting process of the cutting device 600 may be omitted.

In an embodiment, as illustrated in FIG. 5, the cutting device 600 may irradiate the display panel DP, the adhesive member ADH, and the release film RF with a laser beam LS. The cutting device 600 may be a laser cutting device. However, the cutting device 600 is not limited thereto, and may include various cutting devices such as a blade cutting device and a water-jet cutting device.

In an embodiment, although illustrated in FIG and 5, the apparatus 10 for manufacturing a display device may further include a film removing device 650 for removing the release film RF before the lamination process of the window member WM by the second lamination device 700. The release film RF may be removed before the lamination process of the window member WM. Herein, it would be understood that the film removing device is a conventional film removing device used for removing a release film, and any detailed structure, i.e., conventional features, thereof will be omitted for convenience of description.

The second lamination device 700 may laminate the window member WM on the display panel DP and the adhesive member ADH. In an embodiment, as illustrated in FIG. 5, the second lamination device 700 may be a roll lamination device, but the disclosure is not limited thereto. In an embodiment, for example, the second lamination device 700 may be a vacuum lamination device.

The apparatus 10 for manufacturing a display device according to an embodiment may increase the process efficiency and the productivity by applying the adhesive material OCR onto the release film RF through the roll-to-roll process.

In a conventional method of directly applying the adhesive material OCR onto the display panel DP, the adhesive member ADH may be formed through loading onto a stage, plasma treatment, alignment with the application head 200, applying, curing, and unloading.

According to the apparatus 10 for manufacturing a display device according to an embodiment, in the case of applying the adhesive material OCR onto the release film RF, it may not be desired to accurately align the release film RF with the application head 200 as in the case of directly applying the adhesive material OCR onto the display panel DP. Since the alignment marks MRK are applied onto the release film RF as described above, it is only desired to align the release film RF and the display panel DP with each other when the display panel DP is laminated on the release film RF, and it may not be desired to accurately align the release film RF with the application head 200. Therefore, an alignment process time may be shortened.

In an embodiment, when the adhesive material OCR is applied onto the release film RF, it may not be desired to improve adhesive strength between the adhesive material OCR and an applied surface through plasma treatment, and thus, a plasma treatment process may also be omitted. In such an embodiment, since the roll-to-roll process is used, a continuous process is possible, such that loading and unloading processes may also be shortened.

In a case where an existing solid optical clear adhesive (OCA) is used, a time used for preparing processes such as a process of reinstalling a stage, a process of resetting alignment, and a process of resetting an application range for each type of the display device DD, which is a production subject, may increase. According to the apparatus 10 for manufacturing a display device according to an embodiment, since the release film RF, which is a standard, is used, preparation processes such as the process of reinstalling a stage and the process of resetting alignment may be omitted, and only the process of resetting an application range to be performed, and thus, a preparation time used for each type of the display device DD may be shortened.

In addition, facility construction and equipment costs may also be minimized by shortening or omission of the processes described above.

Hereinafter, a method for manufacturing a display device according to an embodiment will be described.

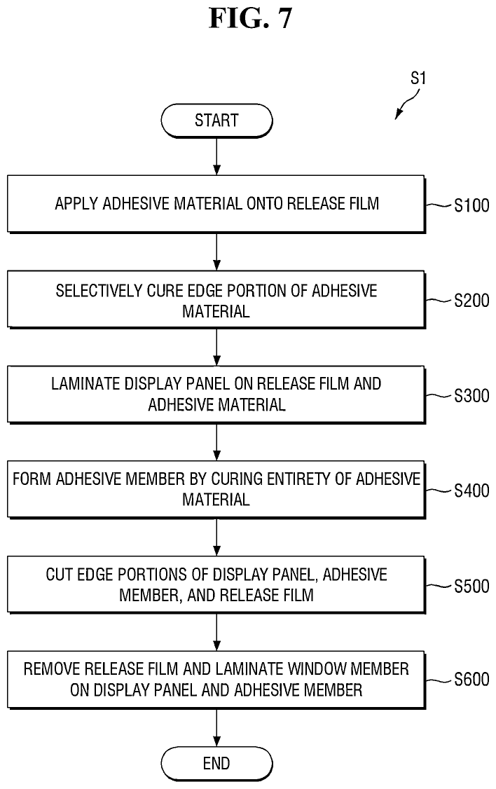

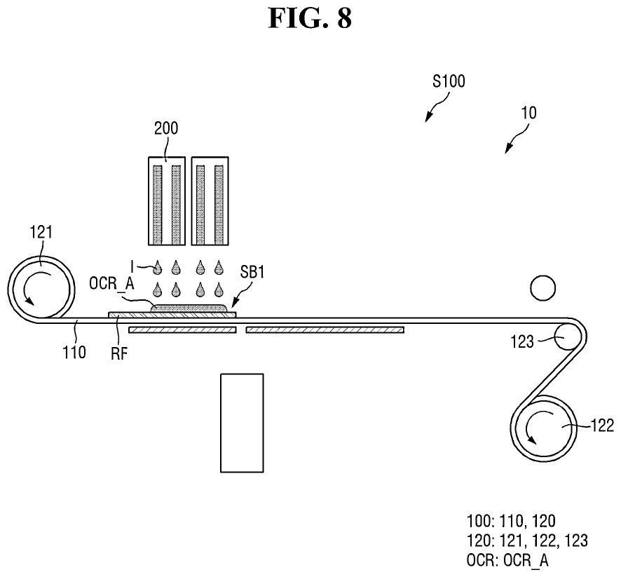

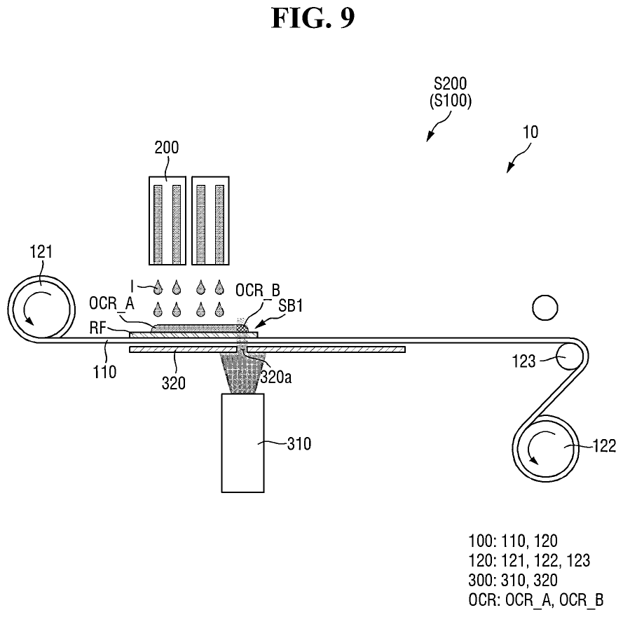

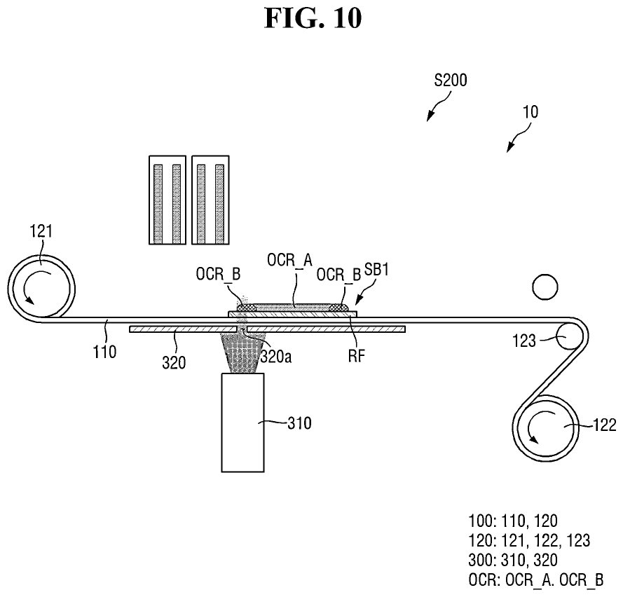

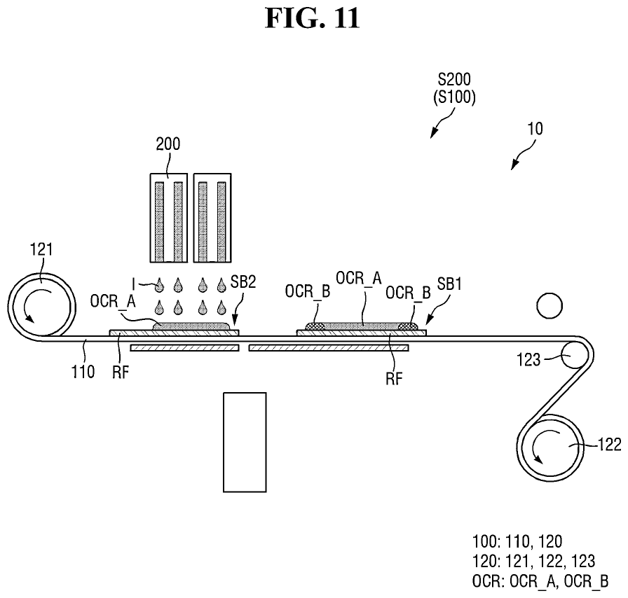

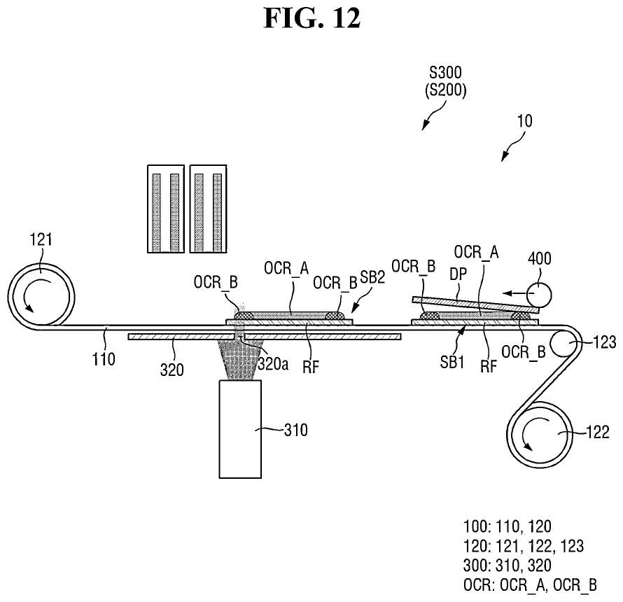

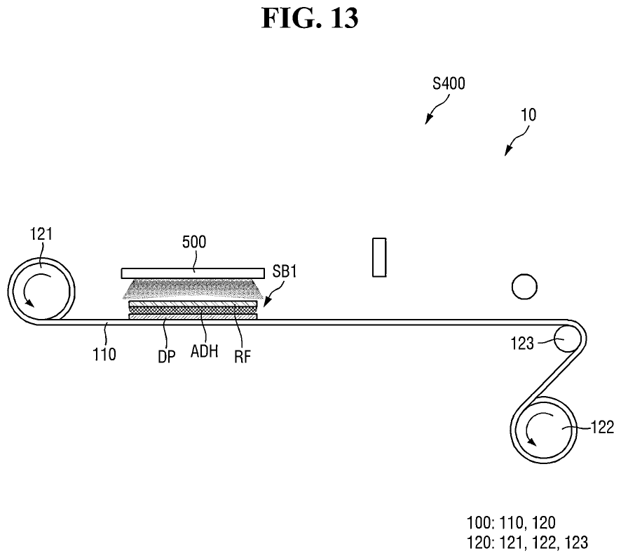

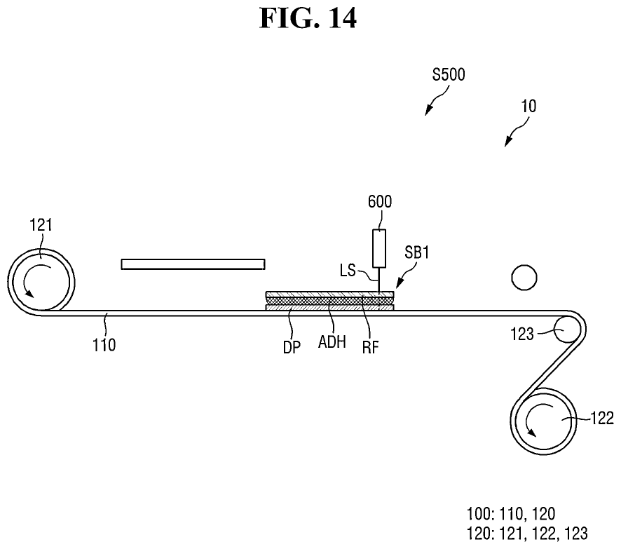

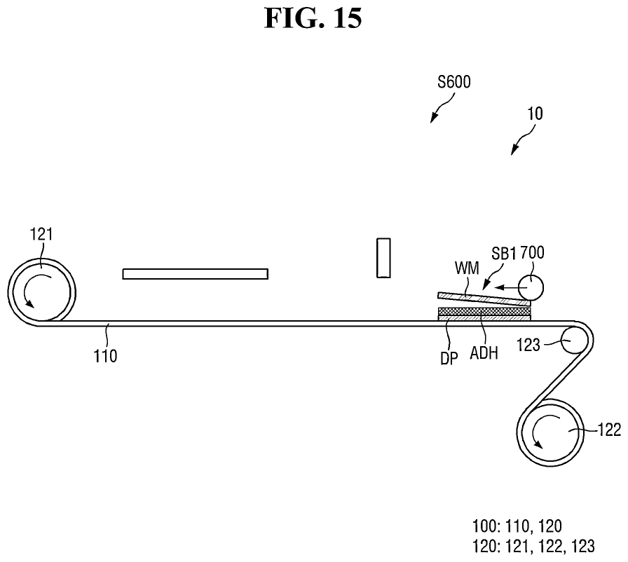

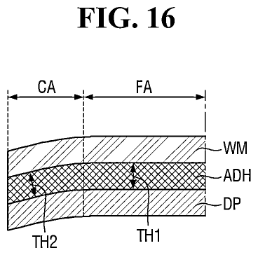

FIG. 7 is a flowchart illustrating a method for manufacturing a display device according to an embodiment. FIG. 8 is a cross-sectional view illustrating process S100 of FIG. 7. FIG. 9 is a cross-sectional view illustrating processes S100 and S200 of FIG. 7. FIG. 10 is a cross-sectional view illustrating process S200 of FIG. 7. FIG. 11 is a cross-sectional view illustrating processes S100 and S200 of FIG. 7. FIG. 12 is a cross-sectional view illustrating processes S200 and S300 of FIG. 7. FIG. 13 is a cross-sectional view illustrating process S400 of FIG. 7. FIG. 14 is a cross-sectional view illustrating process S500 of FIG. 7. FIG. 15 is a cross-sectional view illustrating process S600 of FIG. 7. FIG. 16 is a cross-sectional view illustrating a portion of a display device in a state in which a window member is laminated on the display panel according to an embodiment.

Referring to FIGS. 7 to 16, a method S1 of manufacturing a display device according to an embodiment may include applying the adhesive material onto the release film (S100), selectively curing the edge portion of the adhesive material (S200), laminating the display panel on the release film and the adhesive material (S300), forming the adhesive member by curing the entirety (or an entire portion) of the adhesive material (S400), cutting edge portions of the display panel, the adhesive member, and the release film (S500), and removing the release film and laminating the window member on the display panel and the adhesive member (S600).

As illustrated in FIG. 8, in the process of applying the adhesive material onto the release film (S100), the application head 200 may apply the ink I onto a first subject SB1. The ink I may include a pre-cured adhesive material OCR_A having a liquid form. The first subject SB1 may include the release film RF.

The release film RF may move in one direction by the carrier film 110, and the application head 200 may apply the adhesive material OCR onto the release film RF.

As illustrated in FIGS. 9 and 10, in the process of selective curing the edge portion of the adhesive material (S200), the selective curing module 300 may selectively cure a portion of the adhesive material OCR of the first subject SB1.

The first curing device 310 may generate a post-cured adhesive material OCR_B by curing the pre-cured adhesive material OCR_A of the edge portion PA by irradiating the pre-cured adhesive material OCR_A with light when the edge portion PA of the adhesive material OCR of the first subject SB1 overlaps the opening 320a or the transmissive area of the light blocking film 320.

In some embodiments, as illustrated in FIG. 9, by disposing the application head 200 and the first curing device 310 so that the horizontal distance between the application head 200 and the first curing device 310 is minimized, an applying process of S100 for the first subject SB1 and a selective curing process of S200 for the first subject SB1 may be simultaneously performed. According to the method S1 for manufacturing a display device according to an embodiment, by shortening a time between the applying process of S100 and the selective curing process of S200, it is possible to minimize expansion of the inclined surface of the edge portion PA due to spreadability of the liquid adhesive material OCR.

However, the disclosure is not limited thereto, and the applying process of S100 for the first subject SB1 and the selective curing process of S200 for the first subject SB1 may also be sequentially performed.

In some embodiments, as illustrated in FIG. 11, an applying process of S100 for a second subject SB2 may be performed simultaneously with the selective curing process of S200 for the first subject SB1. According to the method S1 for manufacturing a display device according to an embodiment, a continuous process may be performed through a roll-to-roll process using the release film RF, such that process efficiency and productivity may be increased.

As illustrated in FIG. 12, in the process of laminating the display panel on the release film and the adhesive material (S300), the first lamination device 400 may laminate the display panel DP on the release film RF and the adhesive material OCR. In an embodiment, for example, the first lamination device 400 may laminate the display panel DP in a roll lamination or vacuum lamination manner.

In some embodiments, a selective curing process of S200 for the second subject SB2 may be performed simultaneously with a panel lamination process of S300 for the first subject SB1.

As illustrated in FIG. 13, in the process of forming the adhesive member by curing the entirety of the adhesive material (S400), the second curing device 500 may entirely cure the adhesive material OCR. In an embodiment, for example, the second curing device 500 may cure the adhesive material OCR using an ultraviolet curing, thermal curing, or natural curing manner. The adhesive member ADH may be formed by curing the adhesive material OCR.

Although not illustrated in FIG. 13, a panel lamination process of S300 for the second subject SB2 may be performed simultaneously with a main curing process of S400 for the first subject SB1.

As illustrated in FIG. 14, in the process of cutting the edge portions of the display panel, the adhesive member, and the release film (S500), the cutting device 600 may cut and remove an edge portion of the first subject SB1. The cutting device 600 may cut and remove the edge including the inclined surface of the adhesive member ADH. In some embodiments, a cutting process of S500 may be omitted.

Although not illustrated in FIG. 14, a main curing process of S400 for the second subject SB2 may be performed simultaneously with the cutting process of S500 for the first subject SB1.

As illustrated in FIG. 15, in the process of removing the release film and the laminating of the window member on the display panel and the adhesive member (S600), the second lamination device 700 may laminate the window member WM on the display panel DP and the adhesive member ADH. In an embodiment, for example, the second lamination device 700 may laminate the window member WM in a roll lamination or vacuum lamination manner.

Although not illustrated in FIG. 15, a cutting process of S500 for the second subject SB2 may be performed simultaneously with a lamination process of the window member of S600 for the first subject SB1.

According to the method S1 for manufacturing a display device according to an embodiment, as illustrated in FIG. 16, where the window member WM has a curved shape, delamination of the adhesive member ADH may be minimized.

In an embodiment, for example, the window member WM may include a flat area FA and a curved area CA. The flat area FA may be positioned generally at the center of the window member WM, and the curved area CA may be positioned generally at an edge portion of the window member WM.

According to the method S1 for manufacturing a display device according to an embodiment, the inclined surface at the edge portion PA of the adhesive material OCR is removed by the cutting process or minimized by the selective curing process, and thus, a thickness TH2 of the adhesive member ADH in an edge area of the adhesive member ADH overlapping the curved area CA and a thickness TH1 of the adhesive member ADH in a central area of the adhesive member ADH overlapping the flat area FA may be substantially the same as each other. Accordingly, delamination of the adhesive member ADH in an area overlapping the curved area CA between the display panel DP and the window member WM may be minimized.

In addition, the main curing is performed before the window member WM is laminated and is performed in a state in which the release film RF is attached, such that a reduction phenomenon in curing degree due to an oxygen inhibition effect is minimized, and thus, adhesive strength of the adhesive member ADH may be improved. Accordingly, the delamination of the adhesive member ADH may be minimized even when the window member WM including the curved area CA is laminated on the adhesive member ADH.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An apparatus for manufacturing a display device, the apparatus comprising:
an application head which applies an adhesive material to a subject; and
a selective curing module which cures a portion of the adhesive material,
wherein the selective curing module cures an edge portion of the adhesive material.

2. The apparatus for manufacturing a display device of claim 1, further comprising a transfer module including a carrier film and a roller group which provides a driving force to the carrier film,
wherein the carrier film provides a space where the subject is seated.

3. The apparatus for manufacturing a display device of claim 2, wherein the application head and the selective curing module are respectively positioned on opposite sides with the carrier film interposed therebetween.

4. The apparatus for manufacturing a display device of claim 3, wherein the carrier film is a light transmitting film.

5. The apparatus for manufacturing a display device of claim 2, wherein the roller group includes an unwinding roller which unwinds the carrier film and a winding roller which winds the carrier film.

6. The apparatus for manufacturing a display device of claim 1, wherein
the selective curing module includes:
a first curing device which irradiates the adhesive material with light; and
a light blocking film which blocks a portion of the light, and
the light blocking film includes a non-transmissive area which blocks a portion of the light and a transmissive area which transmits a portion of the light therethrough.

7. The apparatus for manufacturing a display device of claim 6, wherein the light blocking film is provided with an opening which transmits the light therethrough.

8. The apparatus for manufacturing a display device of claim 1, wherein
the subject includes a release film, and
alignment marks are formed on the release film by the adhesive material applied from the application head.

9. The apparatus for manufacturing a display device of claim 8, wherein the release film is a light transmitting film.

10. The apparatus for manufacturing a display device of claim 1, further comprising a first lamination device which laminates a display panel on the subject to which the adhesive material is applied.

11. The apparatus for manufacturing a display device of claim 10, further comprising a second curing device which entirely cures the adhesive material included in the subject on which the display panel is laminated,
wherein the second curing device forms an adhesive member by curing the adhesive material.

12. The apparatus for manufacturing a display device of claim 11, further comprising a second lamination device which laminates a window member on the subject including the display panel and the adhesive member.

13. The apparatus for manufacturing a display device of claim 12, further comprising a cutting device which cuts an edge portion of the subject.

14. The apparatus for manufacturing a display device of claim 11, wherein
the subject includes a release film, and
the apparatus further comprises a film removing device which removes the release film disposed on the adhesive member.

15. The apparatus for manufacturing a display device of claim 1, wherein the adhesive material includes an optical clear resin having a liquid form.

16. A method for manufacturing a display device, the method comprising:
applying an adhesive material onto a release film;
selectively curing an edge portion of the adhesive material;
laminating a display panel on the release film and the adhesive material;
forming an adhesive member by curing an entirety of the adhesive material; and
removing the release film and laminating a window member on the display panel and the adhesive member.

17. The method for manufacturing a display device of claim 16, wherein the applying the adhesive material and the selectively curing the edge portion of the adhesive material are at least partially simultaneously performed.

18. The method for manufacturing a display device of claim 16, wherein in the laminating the display panel, portions of the adhesive material except for the selectively cured edge portion of the adhesive material are in a liquid form.

19. The method for manufacturing a display device of claim 16, wherein the release film is removed after the entirety of adhesive material is cured.

20. The method for manufacturing a display device of claim 16, further comprising cutting edge portions of the display panel, the adhesive member, and the release film.
